(19) United States
(12) Patent Application Publication
(10) Pub. No.: US 2021/0296488 A1
(43) Pub. Date: Sep. 23, 2021

(54) SHIELDED GATE TRENCH MOSFET HAVING SUPER JUNCTION REGION FOR DC/AC PERFORMANCE IMPROVEMENT

(71) Applicant: Nami MOS CO., LTD., New Taipei City (TW)

(72) Inventor: Fu-Yuan HSIEH, New Taipei City (TW)

(73) Assignee: Nami MOS CO., LTD., New Taipei City (TW)

(21) Appl. No.: 16/823,376

(22) Filed: Mar. 19, 2020

(51) Int. Cl. H01L 29/78; H01L 29/06; H01L 29/10; H01L 29/40

(52) U.S. Cl. CPC H01L 29/7813; H01L 29/0634; H01L 29/408; H01L 29/407; H01L 29/1095

(57) ABSTRACT

A trenched semiconductor power device is disclosed comprising a plurality of trenched gates, each including a gate electrode and a shielded gate electrode forming an oxide charge balance region between adjacent trenched gates; and the trenched semiconductor power device further comprises a super junction structure including a plurality of alternating P and N regions disposed above a substrate and forming a junction charge balance region below the oxide charge balance region for breakdown voltage enhancement, on-resistance and output capacitance reductions.

### FIELD OF THE INVENTION

This invention relates generally to semiconductor devices, and more particularly, to a shielded gate trench MOSFET (Metal Oxide Semiconductor Field Effect Transistor) having oxide charge balance region and super junction region to maintain a stable high breakdown voltage, lower on-resistance and output capacitance.

### BACKGROUND OF THE INVENTION

FIGS. 1A˜1C show three types of shielded gate trench MOSFETs (SGT) which have much lower gate charge and on-resistance compared with traditional single gate trench MOSFETs as results of existence of oxide charge balance region (as illustrated in FIG. 1A) in drift region and thick oxide underneath gate electrode. However, early breakdown always occurs at trench bottom and a degradation of the breakdown voltage is therefore becoming a design and operation limitation.

To improve the early breakdown issue, U.S. Pat. No. 8,159,021 disclosed a SGT MOSFET with double epitaxial layers having two different resistivity, as shown in FIG. 1D. The first epitaxial layer (N1 Epi, as shown in FIG. 1D) has a greater resistivity than the second epitaxial layer (N2 Epi), and the trench bottom located in the first epitaxial layer enhances the breakdown voltage. However, since the breakdown voltage at trench bottom is strongly dependent on trench bottom oxide thickness and trench depth, the breakdown voltage may have wide variation across wafer due to uniformity issue of the thick oxide thickness and trench depth. Moreover, specific on-resistance is higher than the prior arts as shown in FIGS. 1A-1C as result of the higher epitaxial resistivity in the first epitaxial layer (N1 epi, as illustrated) than in the second epitaxial layer (N2 epi, as illustrated).

Therefore, there is still a need in the art of the semiconductor device design and fabrication, particularly for SGT MOSFET design and fabrication, to provide a novel cell structure, device configuration and manufacturing process that making a SGT MOSFET have stable breakdown voltage.

### SUMMARY OF THE INVENTION

The present invention provides a SGT MOSFET having oxide charge balance region between adjacent trenched gates and a super junction functioning as junction charge balance region below trench bottom to ensure that whole drift region is fully depleted and breakdown occurs at middle of adjacent trenched gates without having early breakdown occurring at trench bottom. Sensitivity of breakdown voltage on trench bottom oxide thickness and trench depth is thus significantly relaxed or immunized. Avalanche capability is also enhanced. Moreover, output capacitance Coss (related to shielded gate MOS capacitor and mesa depletion capacitor) of this invention is reduced as result of shallower trench depth without increasing on-resistance comparing with the prior arts.

According to one aspect, the invention features a trenched semiconductor power device comprising a SGT MOSFET formed in an epitaxial layer of a first conductivity type onto a substrate, further comprising: a plurality of trenched gates surrounded by source regions of the first conductivity type encompassed in body regions of a second conductivity type near a top surface of the epitaxial layer, wherein each of the trenched gates includes a gate electrode and a shielded gate electrode; an oxide charge balance region formed between adjacent of the trenched gates; a super junction structure comprising a plurality of alternating P and N regions disposed above the substrate and below the oxide charge balance regions; the shielded gate electrode being insulated from the epitaxial layer by a first insulating film and the gate electrode being insulated from the epitaxial layer by a second insulting film having a less thickness than the first insulating film, the shielded gate electrode and the gate electrode being insulated from each other; and the body regions, the shielded gate electrodes and the source regions being shorted to a source metal through a plurality of trenched contacts.

According to another aspect, in some preferred embodiments, the substrate has the first conductivity type and the epitaxial layer comprises a single epitaxial layer having uniform doping concentration. In some other preferred embodiments, the substrate has the first conductivity type and the epitaxial layer comprises a lower epitaxial layer with resistivity R1 and an upper epitaxial layer with resistivity R2, wherein the relationship between R1 and R2 can be R1>R2 or R2>R1. In some other preferred embodiments, the substrate has second conductivity type and the epitaxial layer comprises a single epitaxial layer having uniform doping concentration with resistivity R, the trenched semiconductor power device further comprises a buffer layer of the first conductivity type with resistivity Rn sandwiched between the substrate and the epitaxial layer, wherein R>Rn. In some other preferred embodiments, the substrate has the second conductivity type, the epitaxial layer comprises a lower epitaxial layer with resistivity R1 and an upper epitaxial layer with resistivity R2, the trenched semiconductor power device further comprises a buffer layer of the first conductivity type with resistivity Rn sandwiched between the substrate and the lower epitaxial layer, wherein the relationship between R1, R2 and Rn can be R1>R2>Rn or R2>R1>Rn.

According to another aspect, in some preferred embodiments, the P regions of the super junction structure are mainly disposed below bottoms of the shielded gate electrodes and touch to bottom surface of the epitaxial layer. In some other preferred embodiments, the P regions of the super junction structure are mainly disposed below bottoms of the shielded gate electrodes without touching to bottom surface of the epitaxial layer.

According to another aspect, in some preferred embodiment, the shielded gate electrode is disposed in the middle of each trenched gate and the gate electrode is disposed surrounding upper portion of the shielded gate electrode, the gate electrode and the shielded gate electrode are insulated from each other by the second insulating film. In some other preferred embodiments, the shielded gate electrode is disposed in lower portion of each trenched gate, and is insulated from the epitaxial layer by the first insulating film, the gate electrode is disposed in upper portion of each trenched gate, and is isolated from the shielded gate electrode by a third insulating film. More preferred, the first insulating film is a single oxide film having uniform thickness, or the first insulating film has multiple stepped oxide structure having greatest thickness along bottom of the trenched gate.

According to another aspect, in some preferred embodiments, the substrate has the second conductivity type and the trenched semiconductor power device further comprises: a buffer layer of the first conductivity type formed sandwiched between the substrate and the epitaxial layer; and a plurality of heavily doped regions of the first conductivity type formed in the substrate to form a plurality of alternating P+ and N+ regions.

According to another aspect, in some preferred embodiments, the trenched semiconductor power device further comprises a charge storage region of the first conductivity type encompassed in the epitaxial layer and below the body regions, wherein the charge storage region has a higher doping concentration than the epitaxial layer.

According to another aspect, the first conductivity type is N type and the second conductivity type is P type; or the first conductivity type is P type and the second conductivity type is N type.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A is a cross-sectional view of a SGT MOSFET of prior art.

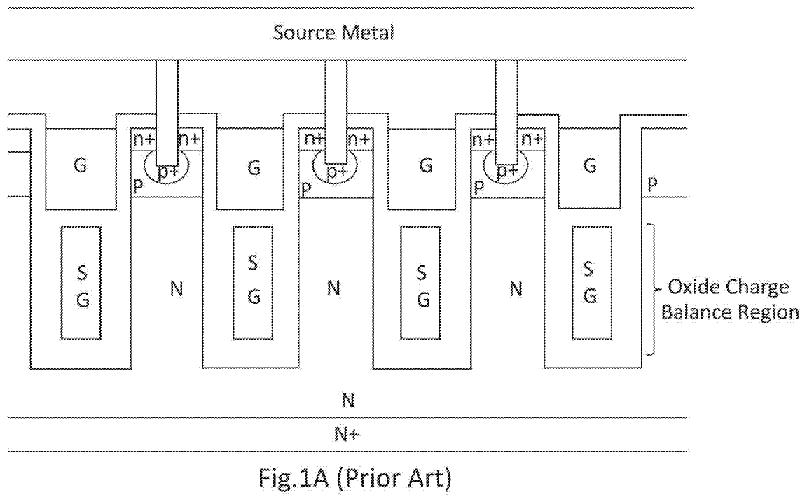

FIG. 1B is a cross-sectional view of another SGT MOSFET of prior art.

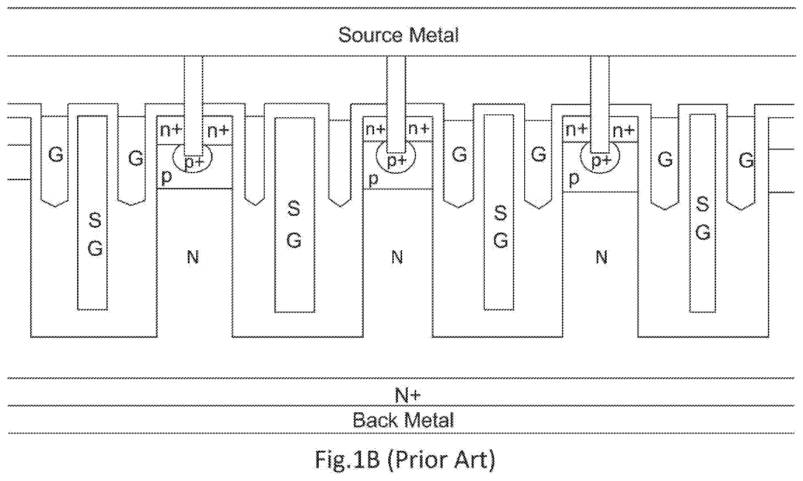

FIG. 1C is a cross-sectional view of another SGT MOSFET of prior art.

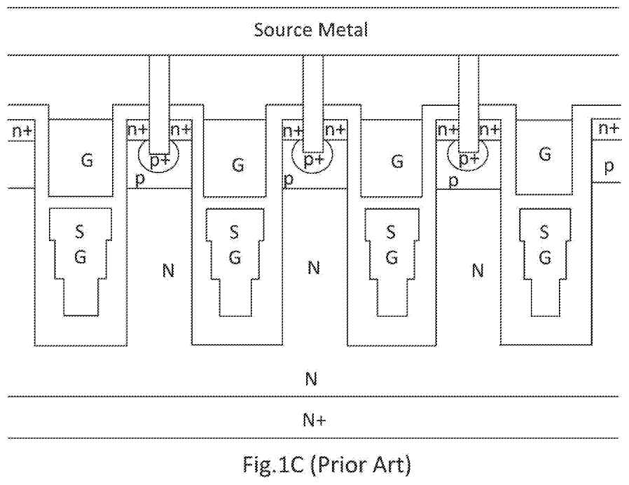

FIG. 1D is a cross-sectional view of another SGT MOSFET of prior art.

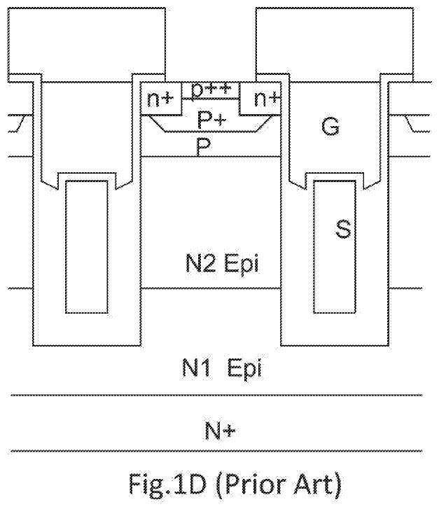

FIG. 2A is a cross-sectional view of a preferred embodiment according to the present invention.

FIG. 2B is a cross-sectional view of another preferred embodiment according to the present invention.

FIG. 2C is a cross-sectional view of another preferred embodiment according to the present invention.

FIG. 2D is a cross-sectional view of another preferred embodiment according to the present invention.

FIG. 3A is a cross-sectional view of another preferred embodiment according to the present invention.

FIG. 3B is a cross-sectional view of another preferred embodiment according to the present invention.

FIG. 3C is a cross-sectional view of another preferred embodiment according to the present invention.

FIG. 3D is a cross-sectional view of another preferred embodiment according to the present invention.

FIG. 4A is a cross-sectional view of another preferred embodiment according to the present invention.

FIG. 4B is a cross-sectional view of another preferred embodiment according to the present invention.

FIG. 4C is a cross-sectional view of another preferred embodiment according to the present invention.

FIG. 4D is a cross-sectional view of another preferred embodiment according to the present invention.

FIG. 5A is a cross-sectional view of another preferred embodiment according to the present invention.

FIG. 5B is a cross-sectional view of another preferred embodiment according to the present invention.

FIG. 6A is a cross-sectional view of another preferred embodiment according to the present invention.

FIG. 6B is a cross-sectional view of another preferred embodiment according to the present invention.

FIG. 7A is a cross-sectional view of another preferred embodiment according to the present invention.

FIG. 7B is a cross-sectional view of another preferred embodiment according to the present invention.

FIG. 8 is a cross-sectional view of another preferred embodiment according to the present invention.

FIG. 9 is a cross-sectional view of another preferred embodiment according to the present invention.

FIG. 10 is a cross-sectional view of another preferred embodiment according to the present invention.

FIG. 11 is a cross-sectional view of another preferred embodiment according to the present invention.

FIG. 12 is a cross-sectional view of another preferred embodiment according to the present invention.

FIG. 13 is a cross-sectional view of another preferred embodiment according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

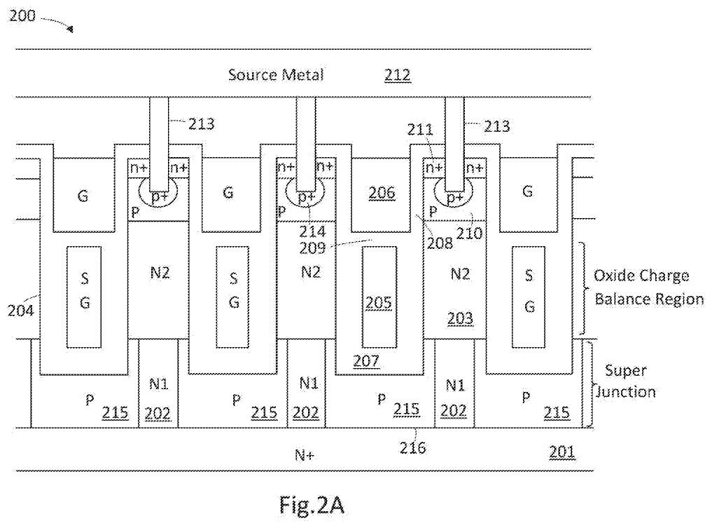

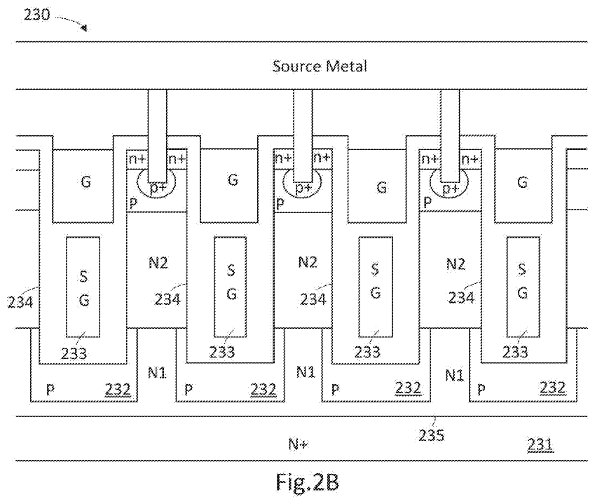

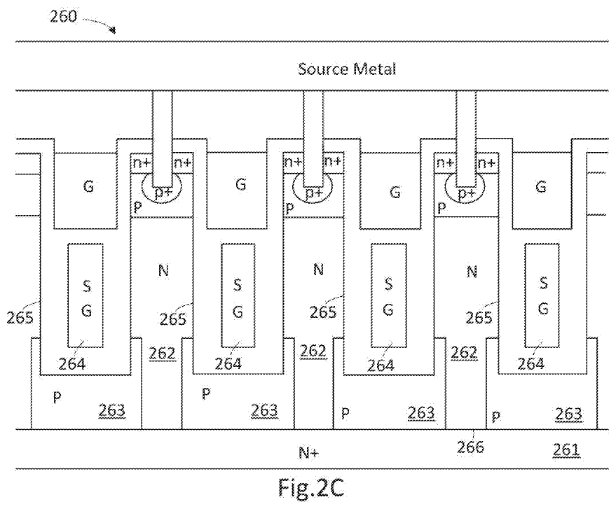

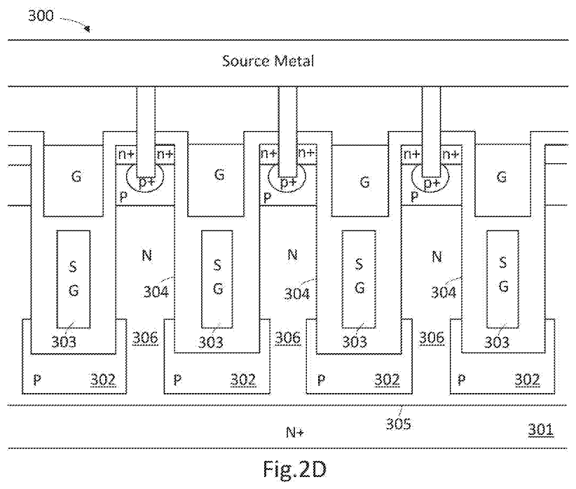

Please refer to FIG. 2A for a preferred embodiment of this invention. A trenched semiconductor power device 200 comprises an N-channel SGT MOSFET formed in an N type epitaxial layer onto an N+ substrate 201, wherein the N type epitaxial layer further comprises a lower N1 epitaxial layer 202 with resistivity R1 and an upper N2 epitaxial layer 203 with resistivity R2, and R1>R2 (the relationship also can be R1<R2). The SGT MOSFET further comprises a plurality of trenched gates 204 extending through the upper N2 epitaxial layer 203 and penetrating into the lower N1 epitaxial layer 202. Inside each of the trenched gates 204, a shielded gate electrode (SG, as illustrated) 205 is disposed in lower portion and a gate electrode 206 is disposed in upper portion, the shielded gate electrode 205 is insulated from the adjacent epitaxial layer by a first insulating film 207 and the gate electrode 206 is insulated from the adjacent epitaxial layer by a second insulating film 208, wherein the second insulating film 208 has a less thickness than the first insulating film 207, meanwhile, the shielded gate electrode 205 and the gate electrode 206 are insulated from each other by a third insulating film 209. Between every two adjacent trenched gates 204, a P body region with n+ source regions 211 thereon is extending near top surface of the upper N2 epitaxial layer 203 and surrounding the gate electrode 206 padded by the second insulating film 208. The P body regions 210, the n+ source regions 211 and the shielded gate electrodes 205 are further shorted to a source metal 212 through a plurality of trenched contacts 213 filled with contact plugs and surrounded by p+ heavily doped regions 214 around bottoms underneath the n+ source regions 211. According to the invention, an oxide charge balance region is therefore formed between adjacent of the trenched gates 204, meanwhile, around bottoms of the trenched gates 204, P regions 215 are introduced into the lower N1 epitaxial layer 202 to form a super junction comprising a plurality of alternating P regions 215 and N regions 202 above the N+ substrate 201 and below the oxide charge balance region to ensure that whole drift region is fully depleted and breakdown occurs at middle of adjacent trenched gates without having early breakdown voltage occurring at trench bottom, and at the same time, to significantly relax the sensitivity of breakdown voltage on trench bottom thickness and trench depth. According to this embodiment, the P regions 215 are mainly disposed below bottoms of the shielded gate electrodes 205 in the trenched gates 204 and touch to bottom surface 216 of the epitaxial layer.

Please refer to FIG. 2B for another preferred embodiment of the present invention, the N-channel trenched semiconductor power device 230 has a similar structure to FIG. 2A, except that, in FIG. 2B, in the super junction structure above the N+ substrate 231, the P regions 232 are mainly disposed below bottoms of the shielded gate electrodes 233 in the trenched gates 234 but without touching to bottom surface 235 of the epitaxial layer.

Please refer to FIG. 2C for another preferred embodiment of the present invention, the N-channel trenched semiconductor power device 260 has a similar structure to FIG. 2A, except that, in FIG. 2C, the epitaxial layer only comprises a single N epitaxial layer 262 above the N+ substrate 261, and the super junction structure comprises a plurality of alternating P regions 263 and N regions 262, wherein the P regions 263 are mainly disposed below bottoms of the shielded gate electrodes 264 in the trenched gates 265 and touch to bottom surface 266 of the N epitaxial layer 262.

Please refer to FIG. 2D for another preferred embodiment of the present invention, the N-channel trenched semiconductor power device 300 has a similar structure to FIG. 2C, except that, in FIG. 2D, in the super junction structure above the N+ substrate 301, the P regions 302 are mainly disposed below bottoms of the shielded gate electrodes 303 in the trenched gates 304 but without touching to bottom surface 305 of the N epitaxial layer 306.

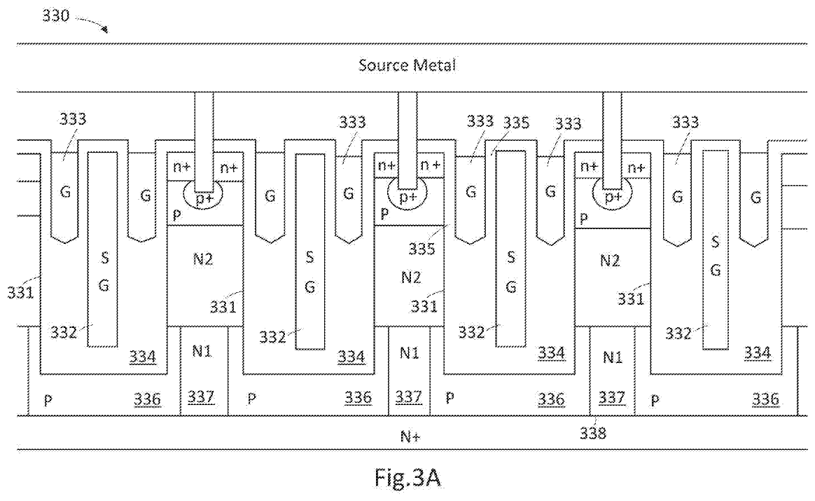

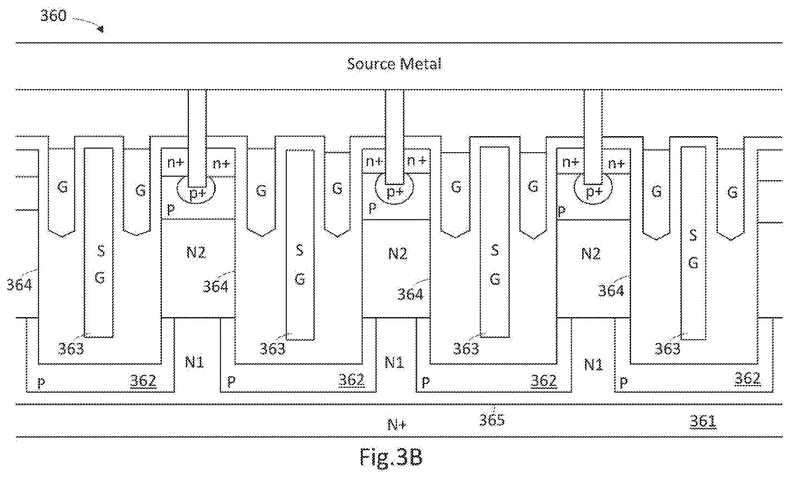

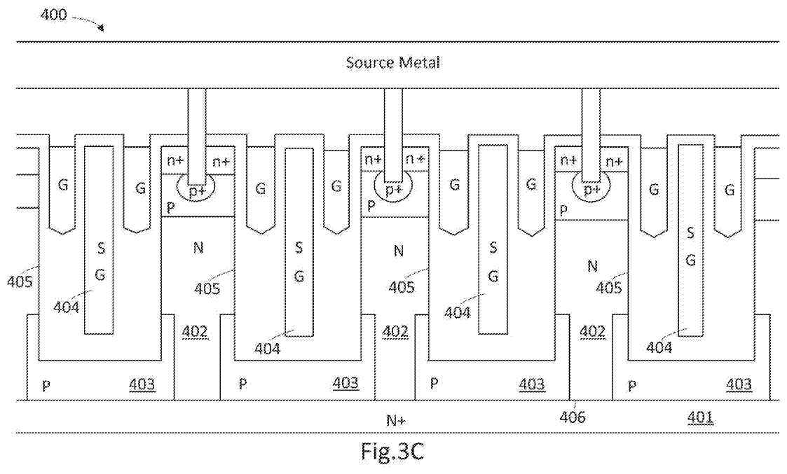

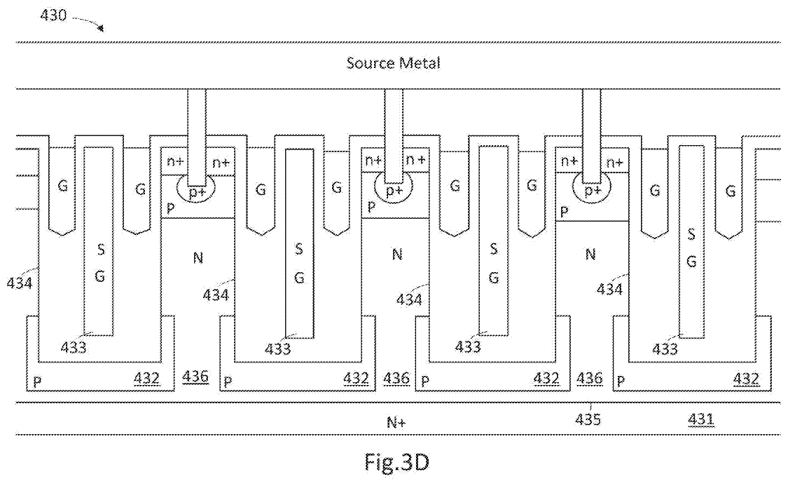

Please refer to FIG. 3A for another preferred embodiment of the present invention, the N-channel trenched semiconductor power device 330 has a similar structure to FIG. 2A, except that, inside each of the trenched gates 331, a shielded gate electrode 332 is disposed in the middle and a gate electrode 333 is disposed surrounding upper portion of the shielded gate electrode 332, the shielded gate electrode 332 is insulated from the epitaxial layer by the first insulating film 334, the gate electrode 333 is insulated from the epitaxial layer by the second insulating film 335, meanwhile, the gate electrode 333 and the shielded gate electrode 332 are insulated from each other also by the second insulating film 335. In the SGT MOSFET, the epitaxial layer comprises the same double epitaxial structure as FIG. 2A and the super junction structure comprises a plurality of alternating P regions 336 and the lower N1 epitaxial layer 337, wherein the P regions 336 are mainly disposed below bottoms of the shielded gate electrodes 332 in the trenched gates 331 and touch to bottom surface 338 of the epitaxial layer.

Please refer to FIG. 3B for another preferred embodiment of the present invention, the N-channel trenched semiconductor power device 360 has a similar structure to FIG. 3A, except that, in FIG. 3B, in the super junction structure above the N+ substrate 361, the P regions 362 are mainly disposed below bottoms of the shielded gate electrodes 363 in the trenched gates 364 but without touching to bottom surface 365 of the epitaxial layer.

Please refer to FIG. 3C for another preferred embodiment of the present invention, the N-channel trenched semiconductor power device 400 has a similar structure to FIG. 3A, except that, in FIG. 3C, the epitaxial layer only comprises a single N epitaxial layer 402 above the N+ substrate 401, and the super junction structure comprises a plurality of alternating P regions 403 and N epitaxial layer 402, wherein the P regions 403 are mainly disposed below bottoms of the shielded gate electrodes 404 in the trenched gates 405 and touch to bottom surface 406 of the N epitaxial layer 402.

Please refer to FIG. 3D for another preferred embodiment of the present invention, the N-channel trenched semiconductor power device 430 has a similar structure to FIG. 3C, except that, in FIG. 3D, in the super junction structure above the N+ substrate 431, the P regions 432 are mainly disposed below bottoms of the shielded gate electrodes 433 in the trenched gates 434 but without touching to bottom surface 435 of the N epitaxial layer 436.

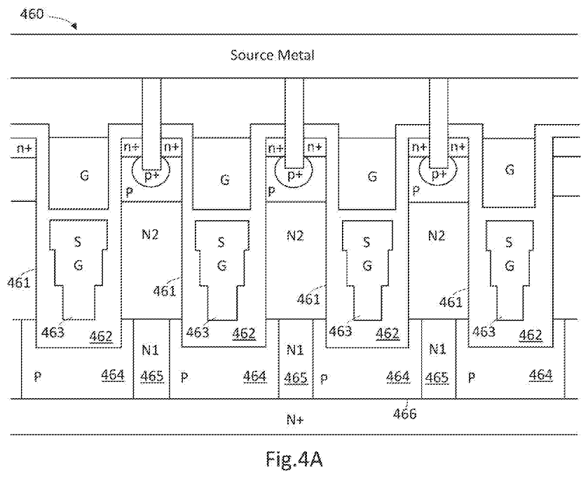

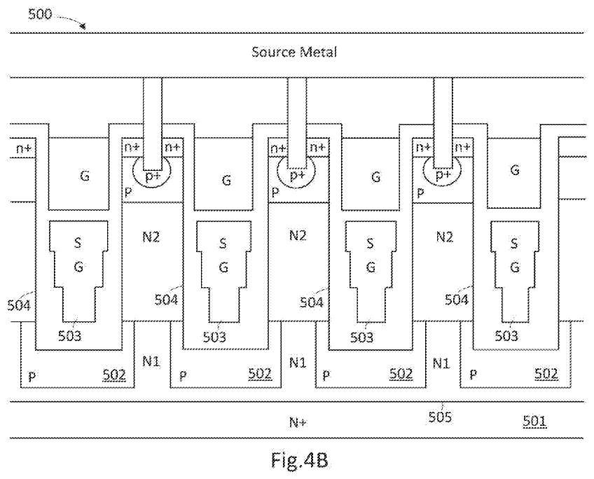

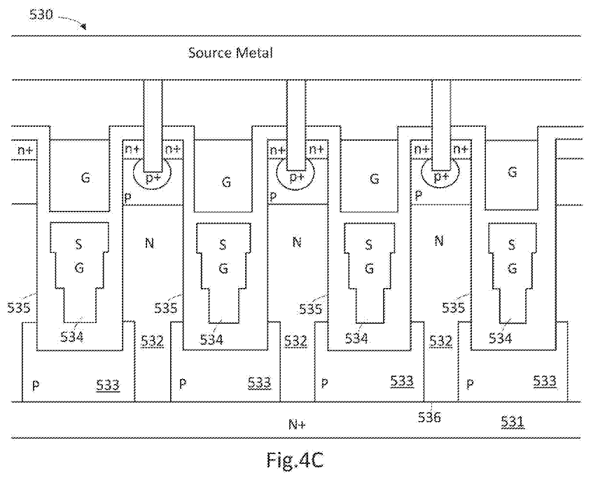

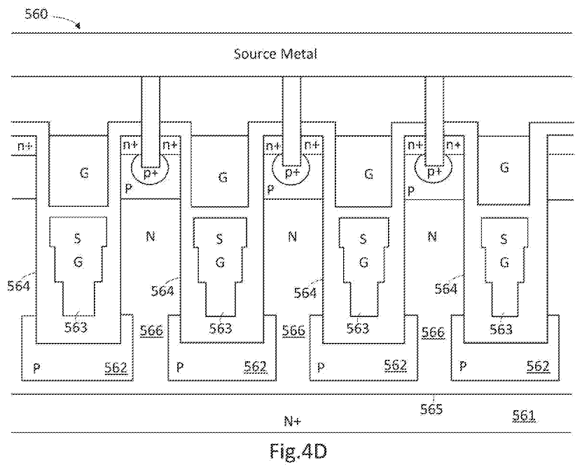

Please refer to FIG. 4A for another preferred embodiment of the present invention, the N-channel trenched semiconductor power device 460 has a similar structure to FIG. 2A, except that, inside each of the trenched gates 461, the first insulating film 462 between the shielded gate electrode 463 and the epitaxial layer has multiple stepped oxide structure having greatest thickness along bottom of the trenched gate 461. In the SGT MOSFET, the epitaxial layer comprises the same double epitaxial structure as FIG. 2A and the super junction structure comprises a plurality of alternating P regions 464 and the lower N1 epitaxial layer 465, wherein the P regions 464 are mainly disposed below bottoms of the shielded gate electrodes 463 in the trenched gates 461 and touch to bottom surface 466 of the epitaxial layer.

Please refer to FIG. 4B for another preferred embodiment of the present invention, the N-channel trenched semiconductor power device 500 has a similar structure to FIG. 4A, except that, in FIG. 4B, in the super junction structure above the N+ substrate 501, the P regions 502 are mainly disposed below bottoms of the shielded gate electrodes 503 in the trenched gates 504 but without touching to bottom surface 505 of the epitaxial layer.

Please refer to FIG. 4C for another preferred embodiment of the present invention, the N-channel trenched semiconductor power device 530 has a similar structure to FIG. 4A, except that, in FIG. 4C, the epitaxial layer only comprises a single N epitaxial layer 532 above the N+ substrate 531, and the super junction structure comprises a plurality of alternating P regions 533 and N epitaxial layer 532, wherein the P regions 533 are mainly disposed below bottoms of the shielded gate electrodes 534 in the trenched gates 535 and touch to bottom surface 536 of the N epitaxial layer 532.

Please refer to FIG. 4D for another preferred embodiment of the present invention, the N-channel trenched semiconductor power device 560 has a similar structure to FIG. 4C, except that, in FIG. 4D, in the super junction structure above the N+ substrate 561, the P regions 562 are mainly disposed below bottoms of the shielded gate electrodes 563 in the trenched gates 564 but without touching to bottom surface 565 of the N epitaxial layer 566.

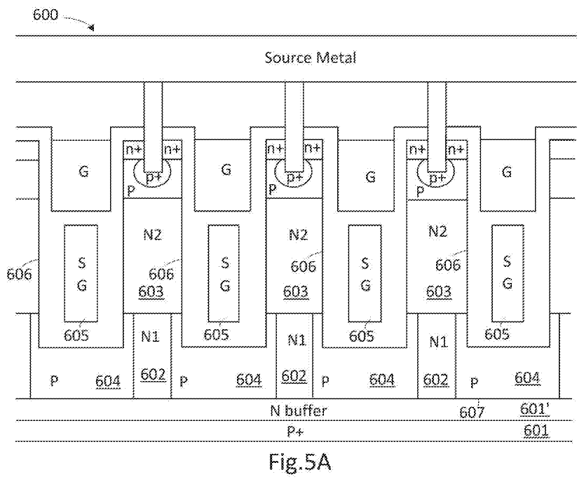

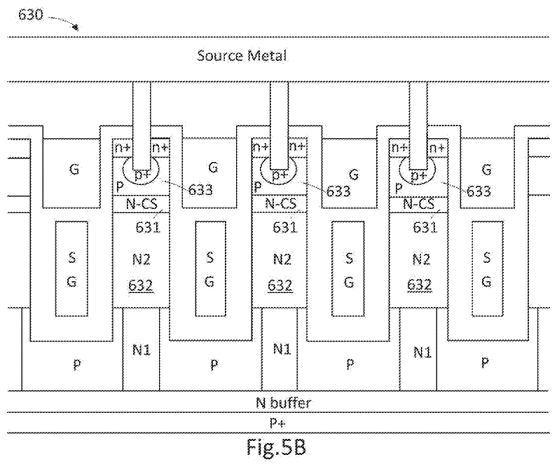

Please refer to FIG. 5A for another preferred embodiment of the present invention, the N-channel trenched semiconductor power device 600 representing an IGBT (Insulating Gate Bipolar Transistor) device has a similar structure to FIG. 2A, except that, in FIG. 5A, the IGBT is formed onto a P+ substrate 601 and further comprises a N buffer layer 601′ with resistivity Rn between the P+ substrate 601 and the epitaxial layer. Similar to FIG. 2A, the epitaxial layer in FIG. 5A comprises a lower N1 epitaxial layer 602 with resistivity R1 and an upper N2 epitaxial layer 603 with resistivity R2, wherein R1>R2>Rn (or the relationship can be R2>R1>Rn). The super junction region comprises a plurality of alternating P regions 604 and the lower N1 epitaxial layer 602, wherein the P regions 604 are mainly disposed below bottoms of the shielded gate electrodes 605 in the trenched gates 606 and touch to bottom surface 607 of the epitaxial layer.

Please refer to FIG. 5B for another preferred embodiment of the present invention, the N-channel trenched semiconductor power device 630 has a similar structure to FIG. 5A, except that, the IGBT in FIG. 5B further comprises a plurality of N charge storage region (N-CS, as illustrated) 631 encompassed in the upper N2 epitaxial layer 632 and below the P body regions 633, wherein the N charge storage regions 631 has a higher doping concentration than the upper N2 epitaxial layer 632.

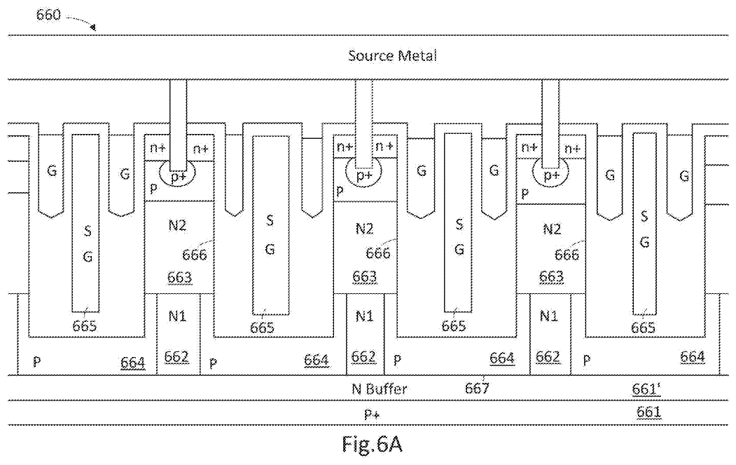

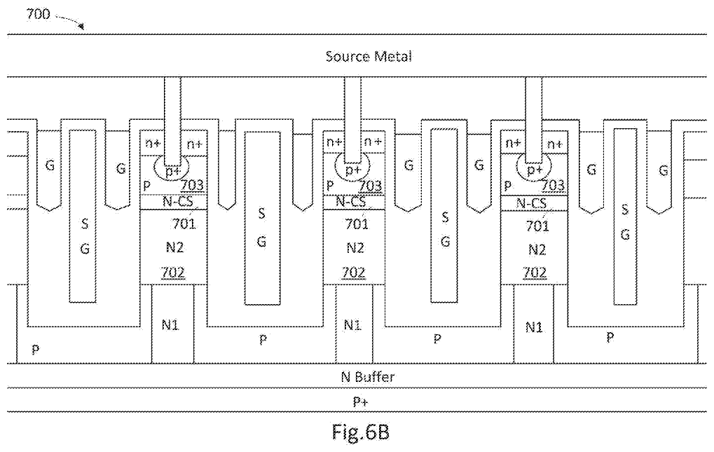

Please refer to FIG. 6A for another preferred embodiment of the present invention, the N-channel trenched semiconductor power device 660 representing an IGBT device has a similar structure to FIG. 3A, except that, in FIG. 6A, the IGBT is formed onto a P+ substrate 661 and further comprises a N buffer layer 661′ with resistivity Rn between the P+ substrate 661 and the epitaxial layer. Similar to FIG. 3A, the epitaxial layer in FIG. 6A comprises a lower N1 epitaxial layer 662 with resistivity R1 and an upper N2 epitaxial layer 663 with resistivity R2, wherein R1>R2>Rn (or the relationship can be R2>R1>Rn). The super junction region comprises a plurality of alternating P regions 664 and the lower N1 epitaxial layer 662, wherein the P regions 664 are mainly disposed below bottoms of the shielded gate electrodes 665 in the trenched gates 666 and touch to bottom surface 667 of the epitaxial layer.

Please refer to FIG. 6B for another preferred embodiment of the present invention, the N-channel trenched semiconductor power device 700 has a similar structure to FIG. 6A, except that, the IGBT in FIG. 6B further comprises a plurality of N charge storage region (N-CS, as illustrated) 701 encompassed in the upper N2 epitaxial layer 702 and below the P body regions 703, wherein the N charge storage regions 701 has a higher doping concentration than the upper N2 epitaxial layer 702.

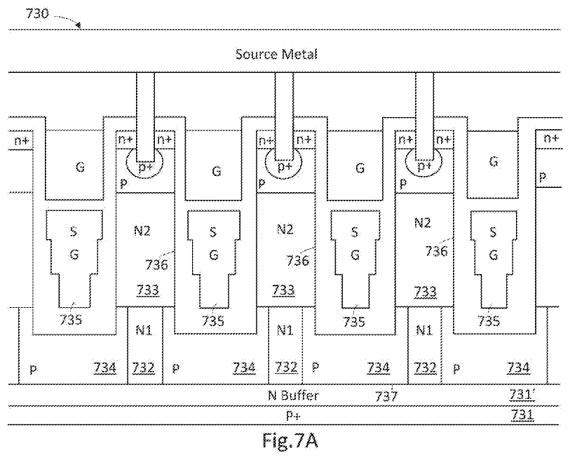

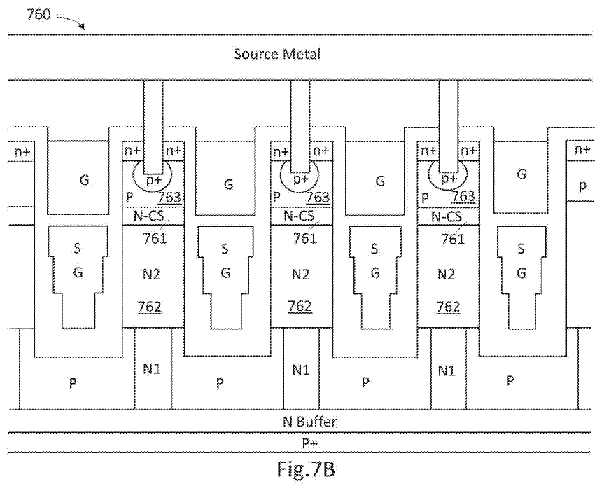

Please refer to FIG. 7A for another preferred embodiment of the present invention, the N-channel trenched semiconductor power device 730 representing an IGBT device has a similar structure to FIG. 4A, except that, in FIG. 7A, the IGBT is formed onto a P+ substrate 731 and further comprises a N buffer layer 731′ with resistivity Rn between the P+ substrate 731 and the epitaxial layer. Similar to FIG. 4A, the epitaxial layer in FIG. 7A comprises a lower N1 epitaxial layer 732 with resistivity R1 and an upper N2 epitaxial layer 733 with resistivity R2, wherein R1>R2>Rn (or the relationship can be R2>R1>Rn). The super junction region comprises a plurality of alternating P regions 734 and the lower N1 epitaxial layer 732, wherein the P regions 734 are mainly disposed below bottoms of the shielded gate electrodes 735 in the trenched gates 736 and touch to bottom surface 737 of the epitaxial layer.

Please refer to FIG. 7B for another preferred embodiment of the present invention, the N-channel trenched semiconductor power device 760 has a similar structure to FIG. 7A, except that, the IGBT in FIG. 7B further comprises a plurality of N charge storage region (N-CS, as illustrated) 761 encompassed in the upper N2 epitaxial layer 762 and below the P body regions 763, wherein the N charge storage regions 761 has a higher doping concentration than the upper N2 epitaxial layer 762.

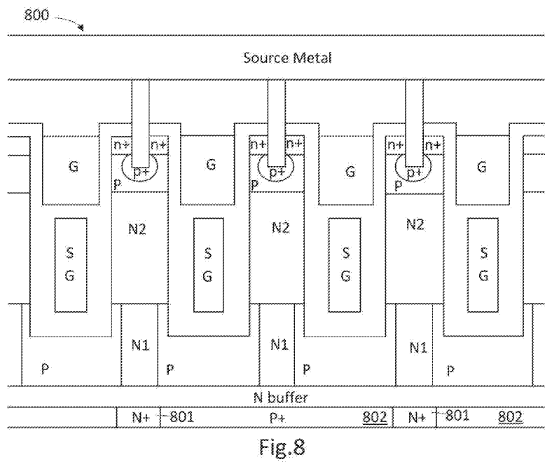

Please refer to FIG. 8 for another preferred embodiment of the present invention, the N-channel trenched semiconductor power device 800 has a similar structure to FIG. 5A, except that, the IGBT in FIG. 8 further comprise a plurality of heavily doped N+ regions 801 formed in the P+ substrate 802 to form a plurality of alternating P+ and N+ regions to serve as integrated reverse conducting diode.

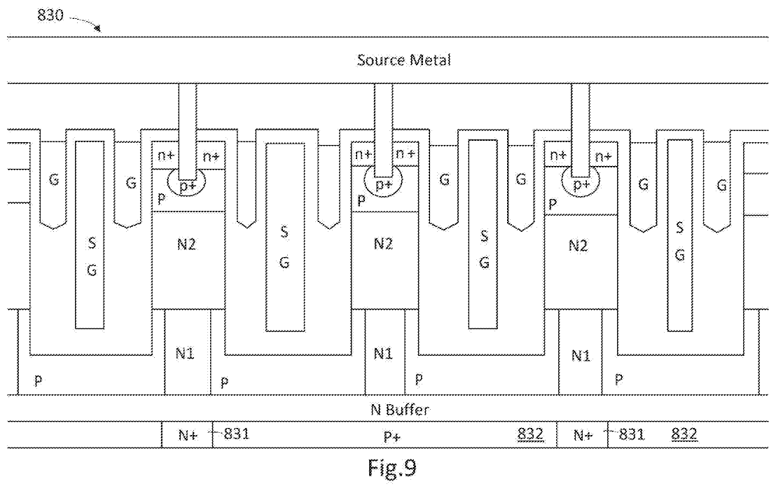

Please refer to FIG. 9 for another preferred embodiment of the present invention, the N-channel trenched semiconductor power device 830 has a similar structure to FIG. 6A, except that, the IGBT in FIG. 9 further comprise a plurality of heavily doped N+ regions 831 formed in the P+ substrate 832 to form a plurality of alternating P+ and N+ regions to serve as integrated reverse conducting diode.

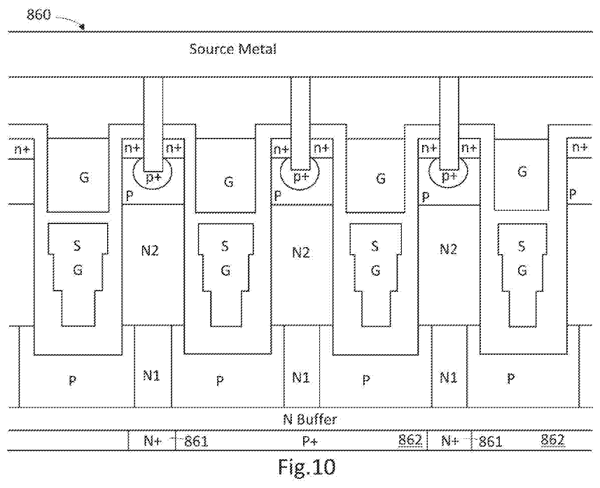

Please refer to FIG. 10 for another preferred embodiment of the present invention, the N-channel trenched semiconductor power device 860 has a similar structure to FIG. 7A, except that, the IGBT in FIG. 10 further comprise a plurality of heavily doped N+ regions 861 formed in the P+ substrate 862 to form a plurality of alternating P+ and N+ regions to serve as integrated reverse conducting diode.

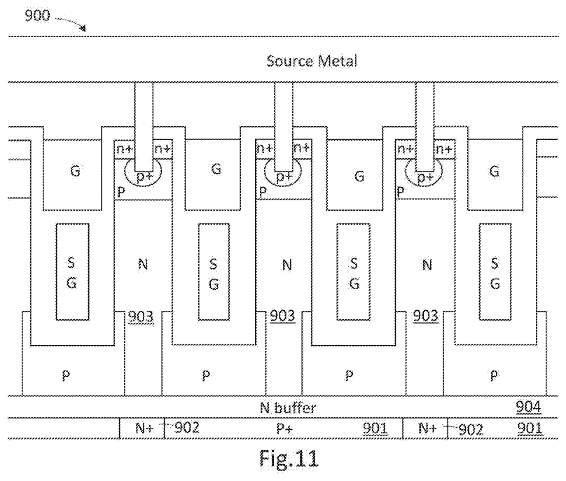

Please refer to FIG. 11 for another preferred embodiment of the present invention, the N-channel trenched semiconductor power device 900 has a similar structure to FIG. 8, except that, the IGBT in FIG. 8 has the double epitaxial layer structure, but the IGBT in FIG. 11 formed onto a P+ substrate 901 having a plurality of N+ regions 902 to form a plurality of alternating P+ and N+ regions serving as integrated reverse conducting diode has a single N epitaxial layer 903 with uniform doping concentration R. The trenched semiconductor power device 900 further comprises a N buffer layer 904 with resistivity Rn sandwiched between the N epitaxial layer 903 and the P+ substrate 901, wherein R>Rn.

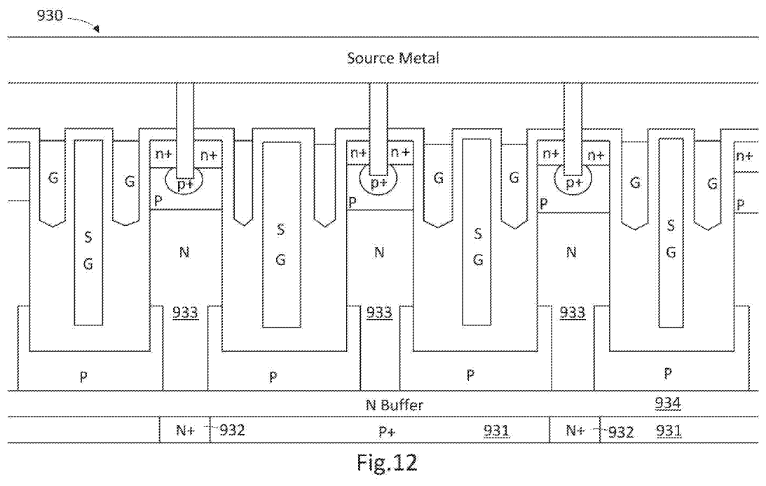

Please refer to FIG. 12 for another preferred embodiment of the present invention, the N-channel trenched semiconductor power device 930 has a similar structure to FIG. 9, except that, the IGBT in FIG. 9 has the double epitaxial layer structure, but the IGBT in FIG. 12 formed onto a P+ substrate 931 having a plurality of N+ regions 932 to form a plurality of alternating P+ and N+ regions serving as integrated reverse conducting diode has a single N epitaxial layer 933 with uniform doping concentration R. The trenched semiconductor power device 930 further comprises a N buffer layer 934 with resistivity Rn sandwiched between the N epitaxial layer 933 and the P+ substrate 931, wherein R>Rn.

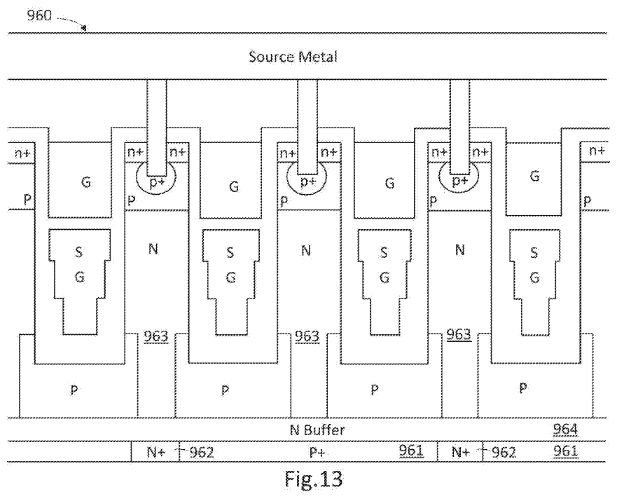

Please refer to FIG. 13 for another preferred embodiment of the present invention, the N-channel trenched semiconductor power device 960 has a similar structure to FIG. 10, except that, the IGBT in FIG. 10 has the double epitaxial layer structure, but the IGBT in FIG. 13 formed onto a P+ substrate 961 having a plurality of N+ regions 962 to form a plurality of alternating P+ and N+ regions serving as integrated reverse conducting diode has a single N epitaxial layer 963 with uniform doping concentration R. The trenched semiconductor power device 960 further comprises a N buffer layer 964 with resistivity Rn sandwiched between the N epitaxial layer 963 and the P+ substrate 961, wherein R>Rn.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trenched semiconductor power device comprising a SGT MOSFET formed in an epitaxial layer of a first conductivity type onto a substrate, further comprising:
a plurality of trenched gates surrounded by source regions of said first conductivity type encompassed in body regions of a second conductivity type near a top surface of said epitaxial layer, each of said trenched gates including a gate electrode and a shielded gate electrode;
an oxide charge balance region formed between adjacent of said trenched gates;
a super junction structure comprising a plurality of alternating P and N regions disposed above said substrate and below said oxide charge balance region;
said shielded gate electrode being insulated from said epitaxial layer by a first insulating film and said gate electrode being insulated from said epitaxial layer by a second insulating film having a less thickness than said first insulating film, said shielded gate electrode and said gate electrode being insulated from each other; and
said body regions, said shielded gate electrodes and said source regions being shorted to a source metal through a plurality of trenched contacts.

2. The trenched semiconductor power device of claim 1, wherein said substrate has said first conductivity type and said epitaxial layer comprises a single epitaxial layer having uniform doping concentration.

3. The trenched semiconductor power device of claim 1, wherein said substrate has said first conductivity type and said epitaxial layer comprises a lower epitaxial layer with resistivity R1 and an upper epitaxial layer with resistivity R2, wherein R1>R2.

4. The trenched semiconductor power device of claim 1, wherein said substrate has said first conductivity type and said epitaxial layer comprises a lower epitaxial layer with resistivity R1 and an upper epitaxial layer with resistivity R2, wherein R1<R2.

5. The trenched semiconductor power device of claim 1, wherein said substrate has said second conductivity type and said epitaxial layer comprises a single epitaxial layer having uniform doping concentration with resistivity R, said trenched semiconductor power device further comprises a buffer layer of said first conductivity type with resistivity Rn sandwiched between said substrate and said epitaxial layer, wherein R>Rn.

6. The trenched semiconductor power device of claim 1, wherein said substrate has said second conductivity type and said epitaxial layer comprises a lower epitaxial layer with resistivity R1 and an upper epitaxial layer with resistivity R2, the shielded gate trench MOSFET further comprises a buffer layer of said first conductivity type with resistivity Rn sandwiched between said substrate and said lower epitaxial layer, wherein R1>R2>Rn.

7. The trenched semiconductor power device of claim 1, wherein said substrate has said second conductivity type and said epitaxial layer comprises a lower epitaxial layer with resistivity R1 and an upper epitaxial layer with resistivity R2, the shielded gate trench MOSFET further comprises a buffer layer of said first conductivity type with resistivity Rn sandwiched between said substrate and said lower epitaxial layer, wherein R2>R1>Rn.

8. The trenched semiconductor power device of claim 1, wherein said P regions of said super junction structure mainly dispose below bottoms of said shielded gate electrodes and touch to bottom surface of said epitaxial layer.

9. The trenched semiconductor power device of claim 1, wherein said P regions of said super junction structure mainly dispose below bottoms of said shielded gate electrodes without touching to bottom surface of said epitaxial layer.

10. The trenched semiconductor power device of claim 1, wherein said shielded gate electrode is disposed in lower portion of each said trenched gate, and is isolated from said epitaxial layer by said first insulating film, said gate electrode is disposed in upper portion of each said trenched gate, and is isolated from said shielded gate electrode by a third insulating film.

11. The trenched semiconductor power device of claim 10, wherein said first insulating film is a single oxide film having uniform thickness.

12. The trenched semiconductor power device of claim 10, wherein said first insulating film has multiple stepped oxide structure having greatest thickness along bottom of said trenched gates.

13. The trenched semiconductor power device of claim 1, wherein said shielded gate electrode is disposed in the middle and said gate electrode is disposed surrounding upper portion of said shielded gate electrode, said gate electrode and said shielded gate electrode are insulated from each other by said second insulating film.

14. The trenched semiconductor power device of claim 1, wherein said substrate has said second conductivity type, said trenched semiconductor power device further comprises:
a buffer layer of said first conductivity type formed sandwiched between said substrate and said epitaxial layer;
a plurality of heavily doped regions of said first conductivity type in said substrate to form a plurality of alternating P+ and N+ regions in said substrate.

15. The trenched semiconductor power device of claim 1 further comprises a charge storage region of said first conductivity type encompassed in said epitaxial layer and below said body region, wherein said charge storage region has a higher doping concentration than said epitaxial layer.

16. The trenched semiconductor power device of claim 1, wherein said first conductivity type is N type and said second conductivity type is P type.

17. The trenched semiconductor power device of claim 1, wherein said first conductivity type is P type and said second conductivity type is N type.
